(19) United States
(12) Patent Application Publication
(10) Pub. No.: US 2015/0205334 A1
(43) Pub. Date: Jul. 23, 2015

(54) HEAT DISSIPATION ASSEMBLY AND PORTABLE ELECTRONIC DEVICE EMPLOYING SAME

(71) Applicant: Chiun Mai Communication Systems, Inc., New Taipei (TW)

(72) Inventors: HUNG-WEI CHUANG, New Taipei (TW); MONG-HAU TSAI, New Taipei (TW)

(21) Appl. No.: 14/579,335

(22) Filed: Dec. 22, 2014

(30) Foreign Application Priority Data
Jan. 17, 2014 (TW) 103101727

(51) Int. Cl. G06F 1/20; H05K 1/02; H05K 7/20; F28F 21/08

(52) U.S. Cl. CPC G06F 1/203; F28F 21/08; H05K 1/0203; H05K 7/2039

(57) ABSTRACT

A heat dissipation assembly including a metal substrate, a heat conducting sheet and a copper foil is provided. The metal substrate has a recess defined therethrough. The heat conducting sheet has a same dimension as the recess, and is embedded in the recess. A thermal conductivity of the heat conducting sheet is greater than a thermal conductivity of the metal substrate. The copper foil is coupled to a surface of the metal substrate. A portable electronic device using the dissipation assembly is also provided. Since the heat conducting sheet has a high thermal conductivity, the metal substrate integrated with the heat conducting sheet can achieve a good strength, low weight and good heat conduct performance.

### FIELD

The subject matter herein generally relates to heat dissipation assemblies, and particular to a heat dissipation assembly for portable electronic device.

### BACKGROUND

A conventional heat dissipation device generally includes a metal plate and a plurality of dissipating fins, which are mounted perpendicularly and equidistantly on an upper surface of the metal plate. Since the electronic devices are to be produced in slim type, the slim type electronic devices cannot provide a volume to contain enough number of dissipating pins to maintain a relative high efficient heat dissipation.

### BRIEF DESCRIPTION OF THE DRAWINGS

Implementations of the present technology will now be described, by way of example only, with reference to the attached figures.

FIG. 1 is an isometric view of one embodiment of a portable electronic device.

FIG. 2 is an exploded view of the portable electronic device as shown in FIG. 1.

FIG. 3 is similar to FIG. 2, but showing the portable electronic device from another angle.

FIG. 4 is a partially exploded view of the portable electronic device.

FIG. 5 is similar to FIG. 4, but showing the portable electronic device from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape or other word that substantially modifies, such that the component need not be exact. For example, substantially cylindrical means that the object resembles a cylinder, but can have one or more deviations from a true cylinder. The term “comprising” when utilized, means “including, but not necessarily limited to”; it specifically indicates open-ended inclusion or membership in the so-described combination, group, series and the like.

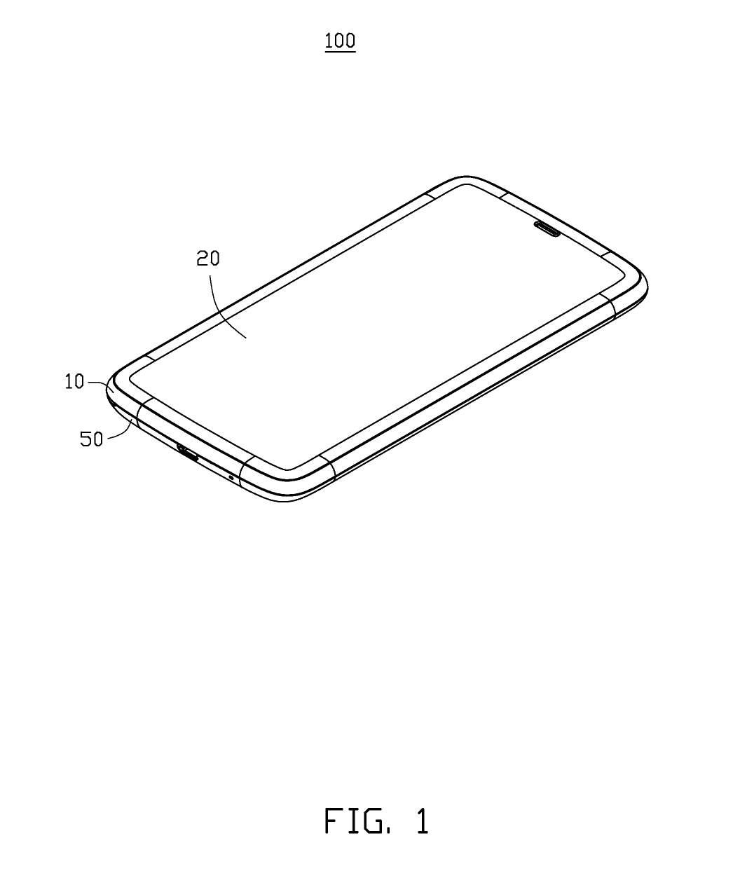

FIG. 1 illustrates an isometric view of one embodiment of a portable electronic device 100 including a front cover 10, a display module 20 attached to the front cover 10 and a battery cover 50.

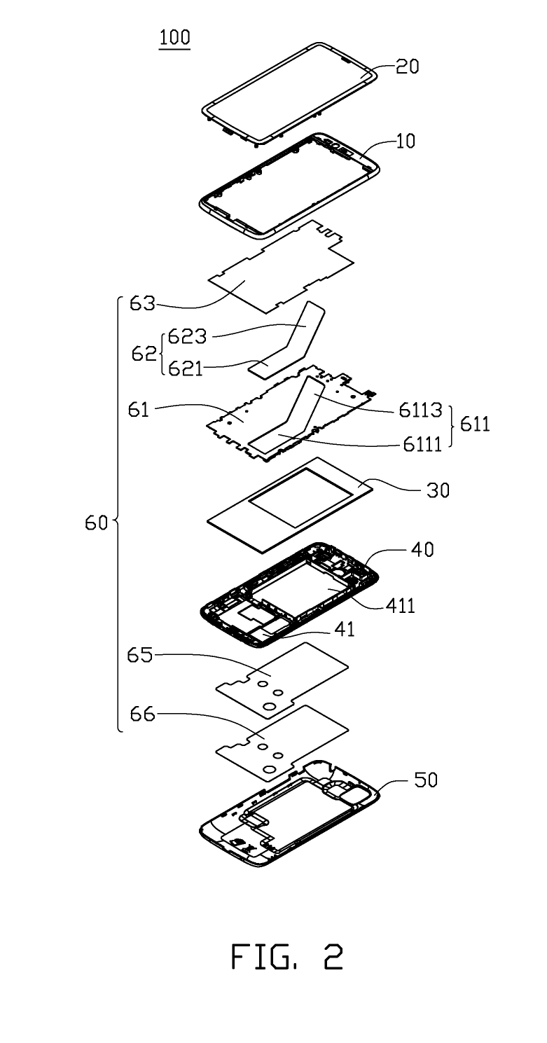

FIG. 2 illustrates an exploded view of the portable electronic device 100 as shown in FIG. 1. The portable electronic device 100 further includes a circuit board 30, a rear cover 40, and a heat dissipation assembly 60.

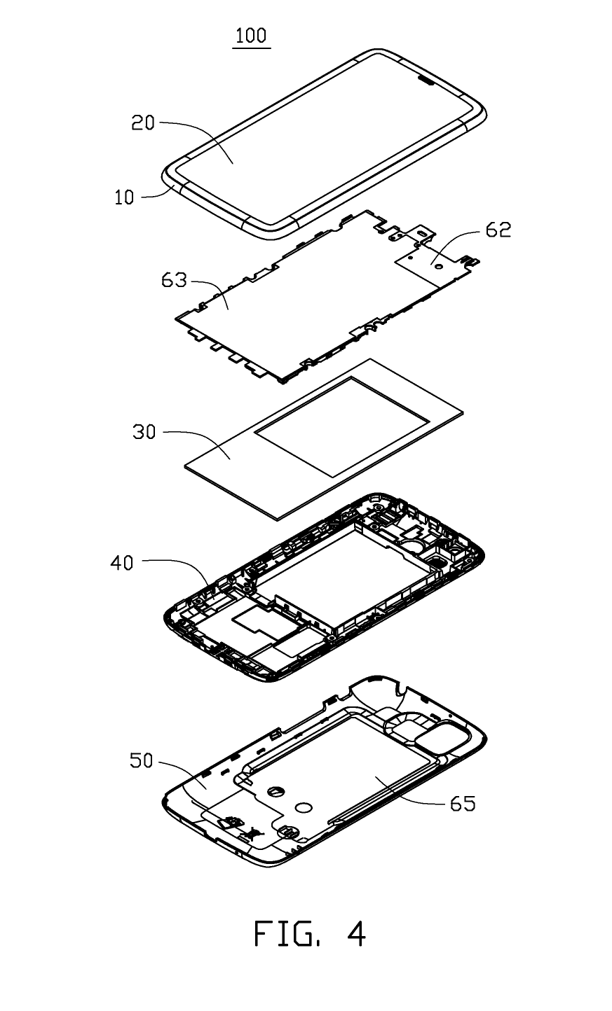

The front cover 10 is a substantially rectangular frame. The display module 20 is attached to a first side of the front cover 10 (also see FIG. 4), and is electronically coupled to the circuit board 30.

The rear cover 40 is attached to a second side of the front cover 10, and defines a mounting groove 41 configured to receive the circuit board 30. A compartment 411 is defined through the rear cover 40 to receive a battery pack (not shown). The battery cover 50 is detachably attached to the rear cover 40 to cover the compartment 411.

The heat dissipation assembly 60 includes a metal substrate 61 and a heat conducting sheet 62. The metal substrate 61 is coupled between the printed circuit board 30 and the display module 20, and has a suitable rigidity to hold the printed circuit board 30 and the display module 20. The metal substrate 61 includes a recess 611. The heat conducting sheet 62 has a same dimension as the recess 611, and is received in the recess 611, and is configured to conduct heat generated by main heat sources, such as central processing unit, radio frequency circuit, and power supply unit, of the printed circuit board 30 to the external environment. The shape and size of the heat conducting sheet 62 is preferred to be determined according to an arrangement of the main heat sources. When the metal substrate 61 and the printed circuit board 30 are assembled together, the heat conducting sheet 62 is located close to the main heat generating components of the printed circuit board 30.

The metal substrate 61 can be made of magnalium alloy, aluminium alloy, or stainless steel. A thermal conductivity of the heat conducting sheet 62 is greater than that of the metal substrate 61. The heat conducting sheet 62 is made of a material having high thermal conductivity, such as copper, aluminium and silver. Since the heat conducting sheet 62 has a high thermal conductivity, the metal substrate 61 integrated with the heat conducting sheet 62 can achieve a good strength, low weight and good thermal conduct performance

The heat conducting sheet 62 can be tightly contacted with the metal substrate 61 to achieve a good heat conduct effect. In another embodiment, the heat conducting sheet 62 can be coupled to the metal substrate 61 by an interface having high thermal conductivity. For example, the heat conducting sheet 62 can be coupled to the metal substrate 61 by welding technology or by a thermal conduct adhesive.

The recess 611 extends from one of two opposite ends of the metal sheet 61 to the other one of the two opposite ends. The recess 611 can be defined through or without breaking through the metal sheet 61. In addition, the recess 611 can be substantially straight or meander-shaped. Accordingly, the heat conducting sheet 62 can be substantially straight or meander-shaped. In at least one embodiment, the recess 611 includes a first sub-recess 6111 and a second sub-recess 6113 extends from the first sub-recess 6111. The first and second sub-recesses 6111, 6113 cooperatively form an obtuse angle. A distal end of the first sub-recess 6111 is located at an end of the metal substrate 61; a distal end of the second sub-recess 6113 is located at another end of the metal substrate 61 opposite the first sub-recess 6111. The heat conducting sheet 62 includes a first arm 621 and a second arm 623 extends from the first mar 621. The first and second arms 621 and 623 are embedded in the first and second sub-recesses 6111 and 6113, respectively. In at least one embodiment, a thickness of the metal substrate 61 is about 0.5 mm; a thickness of the metal substrate 61 is also about 0.5 mm.

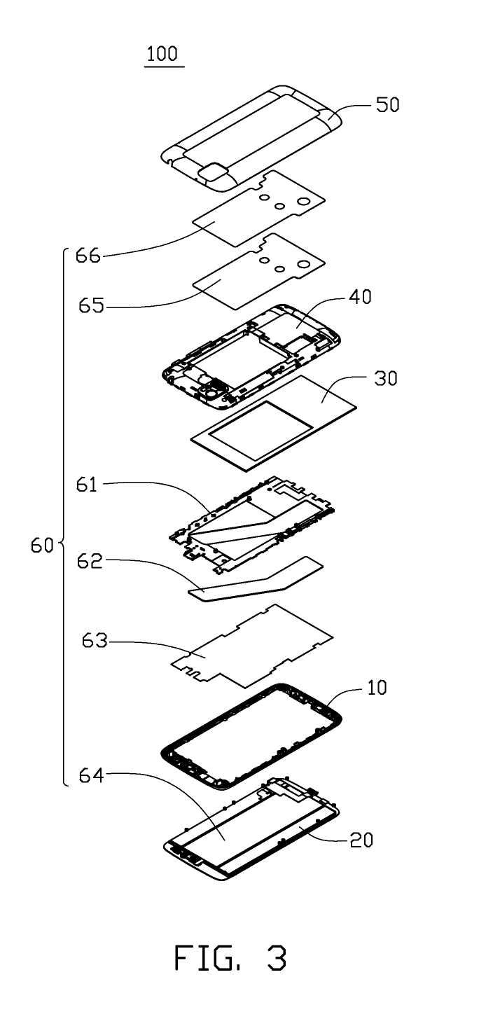

FIG. 3 is similar to FIG. 2, but showing the portable electronic device 100 from another angle. The heat dissipation assembly 60 is also provided with a first copper foil 63, a second copper foil 64, a graphite foil 65 and an adhesive tape 66. The graphite foil 65 is coupled to an inner surface of the battery cover 50 (also see FIG. 4) through the adhesive tape 66, and is configured to dissipating heat generated by the battery. In at least one embodiment, a thickness of the graphite foil 65 is about 0.096 mm.

FIG. 4 illustrates a partially exploded view of the portable electronic device 100. The first copper foil 63 is coupled to a surface of the metal substrate 61 facing the display module 20, and is configured to increase heat dissipation efficiency of the metal substrate 61. In at least one embodiment, a thickness of the first copper foil 63 is about 0.1 mm.

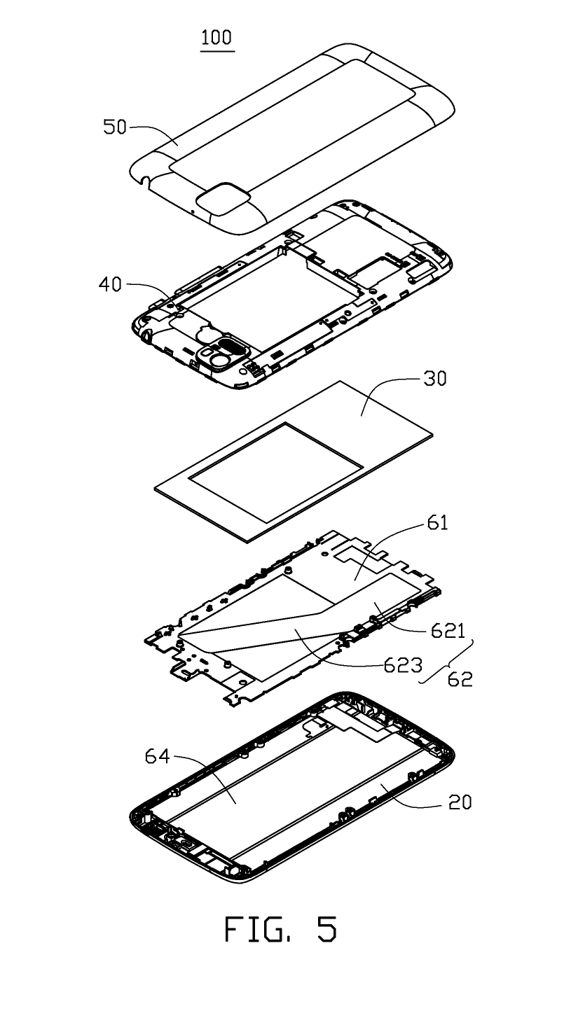

FIG. 5 is similar to FIG. 4, but showing the portable electronic device 100 from another angle. The second copper foil 64 is coupled to a surface of the display module 20 facing the metal substrate 61, and is configured to dissipate heat generated by the display module. In at least one embodiment, the second copper foil 64 is a rectangular sheet, and a thickness of the second copper foil 64 is about 0.05 mm.

The embodiments shown and described above are only examples. Many details are often found in the art. Therefore, many such details are neither shown nor described. Even though numerous characteristics and advantages of the present technology have been set forth in the foregoing description, together with details of the structure and function of the present disclosure, the disclosure is illustrative only, and changes may be made in the detail, including in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A heat dissipation assembly comprising:
a metal substrate having a recess;
a heat conducting sheet having a same dimension as the recess, the heat conducting sheet being received in the recess, a thermal conductivity of the heat conducting sheet is greater than a thermal conductivity of the metal substrate; and
a copper foil coupled to a surface of the metal substrate.

2. The heat dissipation assembly of claim 1, wherein the recess comprises a first sub-recess and a second sub-recess extending from the first sub-recess, the first and second sub-recesses cooperatively form an obtuse angle; a distal end of the first sub-recess is located at an end of the metal substrate; a distal end of the second sub-recess is located at another end of the metal substrate opposite the first sub-recess.

3. The heat dissipation assembly of claim 1, wherein the heat conducting sheet is substantially straight.

4. The heat dissipation assembly of claim 1, wherein the heat conducting sheet is substantially meander-shaped.

5. The heat dissipation assembly of claim 1, wherein the metal substrate is made of one of magnalium alloy, aluminium alloy, and stainless steel.

6. The heat dissipation assembly of claim 1, wherein the heat conducting sheet is made of one of a cooper material, an aluminum material and a silver material.

7. A portable electronic device comprising:
a printed circuit board; and
a heat dissipation assembly comprising:
a metal substrate positioned adjacent to the printed circuit board, the metal substrate having a recess; and
a heat conducting sheet having a same dimension as the recess, the heat conducting sheet being received in the recess; a thermal conductivity of the heat conducting sheet is greater than a thermal conductivity of the metal substrate.

8. The portable electronic device of claim 7, wherein the recess comprises a first sub-recess and a second sub-recess extending from the first sub-recess, the first and second sub-recesses cooperatively form an obtuse angle; a distal end of the first sub-recess is located at an end of the metal substrate; a distal end of the second sub-recess is located at another end of the metal substrate opposite the first sub-recess.

9. The portable electronic device of claim 7, further comprising a display module coupled to the metal substrate, wherein the heat dissipation assembly further comprises a first copper foil coupled to a surface of the metal substrate facing the display module.

10. The portable electronic device of claim 9, wherein the heat dissipation assembly further comprises a second copper foil coupled to a surface of the display module, the second copper foil facing the metal substrate.

11. The portable electronic device of claim 7, wherein the metal substrate is made of one of magnalium alloy, aluminium alloy, and stainless steel.

12. The portable electronic device of claim 7, further comprising a battery cover, a graphite foil, and an adhesive tape, wherein the graphite foil is coupled to an inner surface of the battery cover through the adhesive tape, and is configured to dissipate heat.

13. The portable electronic device of claim 7, wherein the heat conducting sheet is substantially straight.

14. The portable electronic device of claim 7, wherein the heat conducting sheet is substantially meander-shaped.

15. The portable electronic device of claim 7, wherein the heat conducting sheet is made of one of a cooper material, an aluminum material and a silver material.
